(19) United States
(12) Patent Application Publication
(10) Pub. No.: US 2025/0385498 A1
(43) Pub. Date: Dec. 18, 2025

(54) HIGH TEMPERATURE COMPATIBLE ELECTRICAL CONDUIT

(71) Applicant: Raytheon Company, Arlington, VA (US)

(72) Inventors: Traluch En, Tucson, AZ (US); Gerald L. Overby, Saddelbrooke, AZ (US)

(21) Appl. No.: 19/236,320

(22) Filed: Jun. 12, 2025

Related U.S. Application Data
(60) Provisional application No. 63/659,221, filed on Jun. 12, 2024.

(51) Int. Cl. H02G 3/04; H05K 7/20

(52) U.S. Cl. CPC H02G 3/0412; H02G 3/0481; H02G 3/0487; H05K 7/20418

(57) ABSTRACT

An electrical conduit comprising a shell body and a transmission core positioned between a first end portion and a second end portion within the shell body and a tunnel cavity extending through the shell body. The transmission core is suspended within the tunnel cavity and spaced from the shell body and the first electrical connector and the second electrical connector are in communication with the transmission core.

### CLAIM OF PRIORITY

This patent application claims the benefit of priority to U.S. Provisional Application Ser. No. 63/659,221, filed Jun. 12, 2024, which is incorporated by reference herein in its entirety.

### BACKGROUND

Electrical connectors are devices that join electrical circuits together, either temporarily or permanently. Electrical connectors are used to transmit electrical signals such as video, audio, data or electricity from one connector to another connector a wide array of electronic devices and systems. For example, electrical connectors transmit data through cables, wires or the like to carry electrical signals from one electrical connector to another electrical connector.

Different connectors transmit the electrical signal from one connector to the other connector. For example, Universal Serial Bus (USB) connectors, High Definition Media Interface (HDMI) connectors, F-type connectors or XLR connectors are used to transmit electrical signals such as video, audio, data or electricity from one connector to another connector. USB connectors are used in applications that require data or power transmission. USB connectors are often used with personal computer and mobile devices. HDMI connectors are often used to provide high quality digital audio and video connections. HDMI connectors are designed to carry digital signals, eliminating the need for conversion to analog. F-type connectors are a variety of coaxial radio frequency (RF) connectors used with, for example, cable television, satellite, and terrestrial television installations, as well as cable modems and radios. In some examples, F-type connectors provide shielding against interference. XLR connectors are professional audio connectors frequently used in the audio, video, and stage lighting industries for balanced audio signals. XLR connectors are, for example, robust connectors and provide reliable connections,

In examples, RF connectors, such as F-type connector used in coaxial applications are configured to transmit RF signals from one connector to another connector. F-type connectors are sometimes connected to each other with a coaxial cable. For example, coaxial cables are used to transmit data, video, and audio signals. The design of a coaxial cable allows it to carry high-frequency electrical signals. Coaxial cables design is effective for maintaining the integrity and quality of the signal it carries.

### SUMMARY

Managing heat assists in maintaining the efficiency, reliability, and longevity of electrical systems. Techniques such as heat sinks, cooling fans, thermal pastes, and proper ventilation are sometimes used to dissipate heat effectively and keep systems operating within safe temperature limits. In some examples, electrical systems generate heat as a natural byproduct of their operation due to several physical processes and inefficiencies. For example, when an electrical current flows through a conductor, such as wires, resistors or other components that have a resistance, energy is lost from the system in the form of heat. In other examples, heat is generated in electrical systems that involve switching from AC to DC or DC to AC, with inverters or with pulse-width modulated controls.

In some examples, as temperature increases, the resistance of electrical conductors increases. Metals, which are used as conductors, have electrons that move more erratically at higher temperatures, impeding the flow of electrical current. This increased resistance can lead to a reduction in the efficiency of signal transmission. Also, with increased resistance at the strength of the electrical signal decreases as it travels through the conductor (e.g., wire, metal or the like). In systems like cables and wires, higher temperatures sometimes cause the signal to weaken over the distance the signal is carried. For example, heat induces additional electrical noise and interference. At times, this type of noise is directly proportional to the temperature, meaning that as the temperature increases, so does the noise level, which can degrade the quality of the electrical signal.

An electrical conduit including a shell body, two electrical connectors at each end, a transmission core, and a tunnel cavity, optionally provides a system that decreases the likelihood of signal loss or degradation of the signal, as compared to other electrical systems. In an example, a core is suspended within the cavity and spaced from the shell body. The space surrounding the suspended core is, for example, an air insulator. Using air as the insulator, in some examples, decreases signal loss in high heat, or elevated temperature electrical systems.

In other examples, an elongate shell body includes inner and outer shell walls defining a tunnel cavity. A transmission core extends through the tunnel cavity and is positioned away from the inner shell wall. The transmission core is, for example, surrounded by an air insulator. In some examples, the shell body is made from materials such as one or more of titanium, stainless steel alloys, molybdenum, and nickel. In examples, the shell body is a nonpliant structure.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope of the present invention is defined by the appended claims and their legal equivalents.

### BRIEF DESCRIPTION OF THE DRAWINGS

FIG. 1 illustrates an electrical conduit according to at least one example of the present disclosure.

FIG. 2 illustrates a cross section of an electrical conduit according to at least one example of the present disclosure.

FIG. 3 illustrates a perspective view of an electrical conduit according to at least one example of the present disclosure.

FIG. 4 illustrates a cross section of the electrical conduit according to at least one example of the present disclosure.

FIGS. 5A and 5B illustrate a perspective view of the electrical conduit including a heat distribution component according to at least one example of the present disclosure.

FIG. 6 illustrates a method of reducing an electrical signal loss through an electrical adapter.

### DETAILED DESCRIPTION

Electrical conduits, in some examples, include a tube, channel, tunnel or the like that contains components used to transmit, communicate or otherwise transfer an electrical signal from one electrical connector to another electrical connector. In some examples, the electrical conduit transmits one or more of audio, video or data signals in either analog or digital form, or both. In other examples, the conduit is a component of a system to transmit a radio frequency (RF) signal or other high frequency signals.

Radio frequency signals or high frequency signals, in some examples generate heat or elevate the temperature in an electrical system. In other examples, radio frequency or high frequency signals are used in systems where the systems are subject to elevated temperature situations. For example, elevated temperature situations include aerospace applications, foundry work, automotive applications or the like. In examples, the temperatures in these systems and the possibility heat generated along an electrical transmission path increases the possibility of signal loss between connectors.

In some examples, silicon dioxide is used as an insulator surrounding a transmission core extending through a coaxial cable system. In examples using silicon dioxide as an insulator, the system is sealed because silicon dioxide is subject to corrosion due to moisture (such as humidity) and changes in temperature. For instance, a coaxial cable system using silicon dioxide as an insulator, is hermetically sealed to decrease a likelihood of environmental elements from affecting the transmission core and the signal.

A conduit includes the transmission core and is optionally insulated with a dielectric insulator. For example, the dielectric insulator surrounds the transmission core, and the dielectric insulator is surrounded or encased with a metal shield. In some examples, a jacket covers the metal shield, dielectric insulator, and the transmission core. The jacket is, for example, a flexible plastic jacket. In some situations, the flexible plastic jacket allows the system to bend, twist or otherwise transition from a linear form. In examples, bending, twisting or otherwise transitioning from a linear form to a non-linear or arcuate form decreases the signal strength or reliability.

As discussed further herein, electrical systems including a non-pliant conduit optionally includes a housing having a decreased likelihood of bending or flexing, as compared to systems with a conduit formed from pliant plastic or polymer materials. In examples, a transmission core extends within a non-pliant conduit and is surrounded by air. For example, the air acts as an insulator for the transmission core. Using a non-pliant conduit with an air insulator, for example, provides an electrical system such as an electrical conduit that withstands high temperature, both within the system and temperatures that the system is subjected to during use.

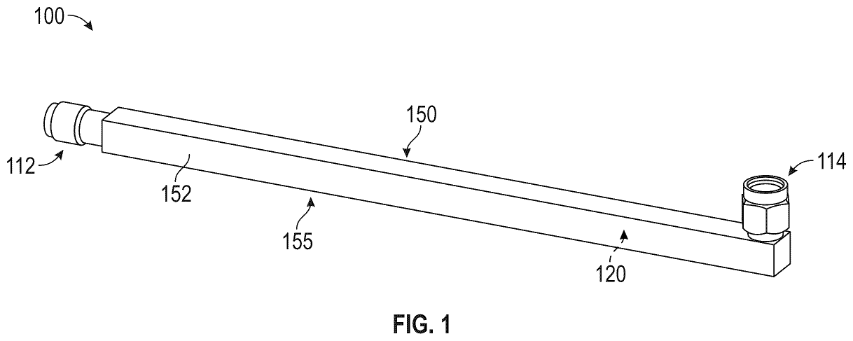

Illustrated in FIG. 1 is an example of an electrical conduit 100. The electrical conduit 100 is an example of a system used to transmit an electrical signal from one point to another point. Transmitting an electrical signal includes, but is not limited to, transmission of audio, video or data. Transmitting an electrical signal includes, but is not limited to, transmission of high frequency waves, radio waves, or electricity as power.

The electrical conduit 100, in some examples, is an electrical adapter. The electrical adapter, for instance, is formed to replace an existing electrical conduit. In other examples, the electrical adapter is an example of an electrical conduit 100 that used as a newly built component for a new or existing electrical system. For example, the electrical adapter as the electrical conduit 100 is an electrical device that is used to connect electrical systems or components that are not directly connected. Hereinafter, “electrical conduit” can also refer to an electrical adapter.

The electrical conduit 100 includes, for example, a conduit body 150. The conduit body 150 is an example of a transmission pathway through which the electrical signal travels. For example, the conduit body 150 spans between a first end portion including a first electrical connector 112 and a second end portion including a second electrical connector 114 through which the electrical signal travels. In examples, the conduit body 150 includes a shell body 155. The shell body 155 has an outer shell wall 152 as an outer face or outer faces of the conduit body 150. The shell body 155 has a structure, or form, that is dictated by the purpose. For example, the shell body 155 is a tube having a cylindrical form. In another example the shell body 155 is a tube having an angular form such as having a cuboid or a prism form. As illustrated in FIG. 1, the shell body 155 is a cuboid including length, such as the distance between the first electrical connector 112 and the second electrical connector 114, that has a greater length dimension than the width and height.

The conduit body 150 includes a shell body 155 formed from an unpliant material. The unpliant material includes, for example, materials that are resistant to bending, flexing or otherwise significantly deforming (e.g., altering in form such as including an arch, curve, angle different from its original form). In some examples, the unpliant material includes at least one or more of titanium, stainless steel alloys, molybdenum and nickel, or the like.

The material selected for the unpliant material includes those that, for example, are resistant to high temperatures. High temperatures include temperatures that, for example, exceed approximately 600 degrees Celsius. In some examples, the material selected for the shell body 155 include those that are able to withstand, or not be significantly affected by temperatures exceeding approximately 600 degrees Celsius. In examples, materials not significantly affected include those materials that do not deform, degrade, or become less effective as relative to its original form. In other examples, the temperature the material withstands includes those less than approximately 600 degrees Celsius.

In some examples, the temperature increase includes gradually increasing over a controlled period of time. In other examples, the temperature increase includes being exposed to relatively quick changes in temperature such as within second or a few minutes. For instance, the temperature increase occurs during launch or descent of an aerospace vehicle, effector or the like. In other examples, the increase in temperature during a process occurring in a foundry such as producing metal castings by melting metal, pouring it into molds, and allowing it to solidify. In yet other examples, the temperature increase occurs in mechanic operation of automotive vehicles, such as within engines and associated electrical systems.

The shell body 155, as stated previously, is a component of the conduit body 150. The conduit body 150 is included in the systems previously described, such as aerospace, automotive, foundry, drilling or the like. In examples, the conduit body 150 is a component of an electrical conduit 100 that effectively transmit electrical signals in elevated temperature environments, as previously described.

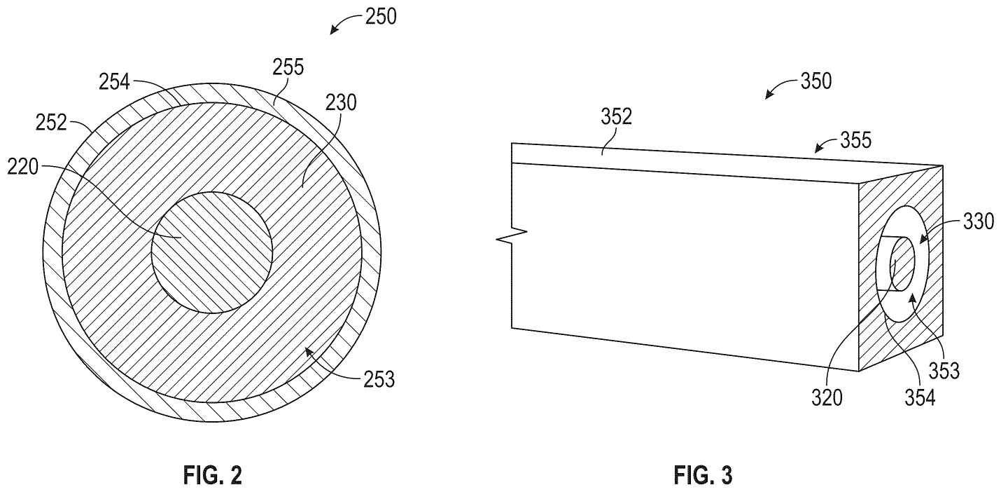

Illustrated in FIG. 2 is a cross section of the conduit body 250. The cross section illustrated in FIG. 2, while illustrated as a lateral cross section of a cylindrical conduit body 250, a cuboid conduit body 250 optionally includes similar components, for example as discussed further in reference to FIG. 3. The conduit body 250 includes, for example, a shell body 255, a transmission core 220 positioned within the shell body 255, and an insulator 230 positioned around the transmission core 220. The shell body 255 includes an outer shell wall 252, as the outer surface or outer surfaces of the shell body 255, and an inner shell wall 254. The inner shell wall 254 is an example of the inner surfaces defining a tunnel cavity 253 extending through the shell body 255. The tunnel cavity 253 includes, for example, the insulator 230 and the transmission core 220. The tunnel cavity 253, while illustrated in a lateral cross section in FIG. 2, extends longitudinally along the length of the conduit body 250, as illustrated and discussed related to FIG. 3. The transmission core 220 extends within the tunnel cavity 253 along the length of the conduit body 250.

The transmission core 220 is, for example, formed from a metal or other material capable of transferring an electrical signal (e.g., data, video, or high frequency signals or the like). In an example, the transmission core 220 is formed from copper, a copper coated alloy, titanium, stainless steel alloys, molybdenum and nickel or other metal or material suitable for transmitting an electrical signal, as specified by the purpose. The transmission core 220 is in some examples, is between approximately 0.2 millimeters and approximately 2.0 millimeters thick. The thickness of the transmission core 220 is dependent on at least the specified purpose.

Illustrated in FIG. 3 is a perspective view a portion of an electrical conduit body 350 including a shell body 355. The shell body 355, in some examples, has an outer shell wall 352 that includes geometric forms such as a several outer shell walls 352 cuboid form having a rectangular (including a square) lateral cross section. In examples, manufacturing a cuboid shell body 355 from an unpliant material, such as molybdenum, aluminum, titanium or other metals or metal alloys, increases consistency of the shape and form during manufacturing of more than one electrical conduit bodies 350 as compared to manufacturing processes for other shapes or forms.

The shell body 355 includes a tunnel cavity 353 extending through the shell body 355. The transmission core 320 is positioned away from the inner shell wall 354. For example, the transmission core 320 is suspended, cantilevered or otherwise retained within the tunnel cavity 353 with an insulator 330 surrounding the transmission core 320. The insulator 330 is, for example, air surrounding the transmission core 320 forming a gap (e.g., void, space) without an intermediary material between the inner shell wall 354 and the transmission core 320.

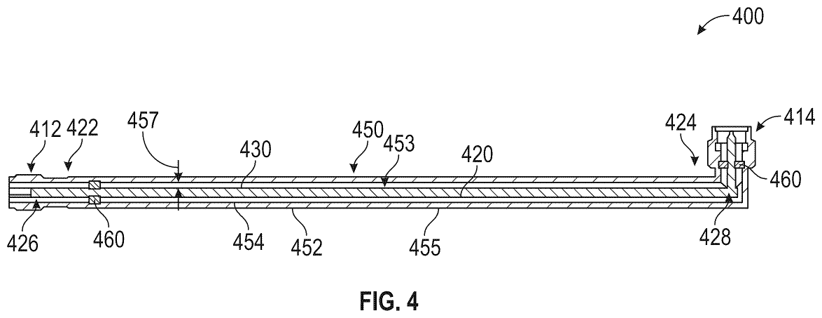

Illustrated in FIG. 4 is a longitudinal cross section of the electrical conduit 400. The electrical conduit 400 is similar to the electrical conduit 100 illustrated in FIG. 1 having similar internal components as discussed related to FIGS. 2 and 3. The electrical conduit 400 includes a conduit body 450 extending between a first electrical connector 412 and a second electrical connector 414. The conduit body 450 includes a conduit body 455. The conduit body 455, for example, includes an outer shell wall 452 defining an outer surface, or outer surfaces, of the conduit body 455. The conduit body 455 is a substantially hollow structure containing a tunnel cavity 453 extending from a first end portion 422 of the conduit body 455 to a second end portion 424 of the conduit body 455. The tunnel cavity 453 is defined by an inner shell wall 454.

In some examples, the conduit body 455 is formed from a material that is capable of withstanding high temperatures. For example, the material withstands temperatures greater than 600 degrees Celsius. For instance, when the material is subjected to temperatures greater than 600 degrees Celsius, the material substantially maintains its original form. (e.g., keeps its form, or only minimally deforms as related to the original form). In some examples, resilient solid materials maintain their electrical performance even at high temperatures, ensuring consistent and reliable signal transmission at temperatures about or exceeding 1500 degrees Celsius. For instance, the material used for the conduit body 455 has melting points greater than 1000 degrees Celsius. Materials that have melting points greater than 1000 degrees Celsius include, for example, titanium, stainless steel alloys, molybdenum, nickel or the like. The conduit body 455, as the outer form of the conduit body 450, in some examples is formed from a material capable of withstanding temperatures exceeding 600 degrees Celsius due the conditions the electrical conduit 400 is subjected to during use. For instance, the conduit body 450 maintains its form to reduce the occurrence of the material degrading or deforming. Deforming or degradation, in some examples, interferes with a signal transmitted through the conduit body 450.

The first electrical connector 412 is connected (e.g., coupled, joined, attached) with a first end portion 422 of the conduit body 450 and the second electrical connector 414 is connected (e.g., coupled, joined, attached) with a second end portion 424 of the conduit body 450. First electrical connector 414 and the second electrical connector 414 are, for example, F-type connectors for a coaxial system or other connectors used to receive or communicate high frequency electrical signals, such as radio frequency. In examples, the first electrical connector 414 and the second end portion 424 are coupled with a transmission core 420. For instance, the first electrical connector 414 is in communication with a first end segment 426 of the transmission core 420 and the second end portion 424 is in communication with a second end segment 428 of the transmission core 420.

The transmission core 420 extends between the first end portion 422 and the second end portion 424 of the conduit body 450. The conduit body 455 houses and protects the transmission core 420 from environmental conditions that could damage, degrade, deform or the like, the transmission core 420. The transmission core 420 is formed from a material that can transmit and electrical signal from the first electrical connector 412 to the second electrical connector 414, or visa versa. For example, the transmission core 420 is formed from materials that are capable of withstanding elevated temperatures (e.g., temperatures greater than 600 degrees Celsius and optionally greater than 1000 degree Celsius). The materials include, for example, molybdenum, copper, or other metals or alloys.

In examples, the first electrical connector 412 is a low temperature connector, or a connector that is subject to temperatures lower than the temperatures generated within the conduit body 450 during use. The distance between the first electrical connector 412 and the second electrical connector 414 is determined, for example, by the amount of heat that is dispersed away from the electrical conduit 400 so the heat is not transferred to the second electrical connector 414. In some examples, the distance between the first electrical connector 412 and the 414 is approximately five inches (approximately 12.7 centimeters). In other examples, the distance between the first electrical connector 412 and the second electrical connector 414 is less than approximately five centimeters if the space of the tunnel cavity 453 is wide enough to insulate and dissipate the heat. Further, if the operating temperature of the system is lower, the distance between the first electrical connector 412 and the second electrical connector 414 can be less than approximately five inches (approximately 12.7 centimeters).

The transmission core 420 bridges the conduit body 450 between the first electrical connector 412 and the second electrical connector 414. For example, the transmission core 420 is positioned to be spaced from the inner shell wall 454 of the conduit body 450. The transmission core 420 is, for instance, suspended, cantilevered, or otherwise positioned within the tunnel cavity 453 with a gap 457 between the transmission core 420 and the inner shell wall 454. The gap 457 of the tunnel cavity 453 surrounds the transmission core 420. The transmission core 420 is retained in position with one or more centering gaskets 460. The one or more centering gaskets 460 are, for example positioned within the tunnel cavity 453. In some examples, the one or more centering gaskets 460 is positioned proximate to one or more of the first end portion or the second end portion 424. In other examples, one or more centering gaskets 460 is position at more central locations within the tunnel cavity 453. The one or more centering gaskets 460 are optionally positioned at locations within the tunnel cavity 453 to maintain the transmission core 420 positioned with the gap 457 extending around the transmission core 420.

The one or more centering gaskets 460 is formed from a material that is capable of withstanding elevated temperatures. For example, the one or more centering gaskets 460 is resistant to deformation or degradation when exposed to temperatures exceeding approximately 600 degrees Celsius.

The gap 457 includes an insulator 430 surrounds the transmission core 420. In examples, the insulator 430 is formed from air. In certain thermal and electrical applications air is used as an insulator because it reduces, for example, unwanted heat transfer and decreases effects of electrical conductivity from external sources. Air is used in certain instances because it has a low dielectric constant and reduces the likelihood of electric fields from transmission, as compared to other solids, liquids or gases. In examples, air withstands certain voltages before it becomes ionized and conducts electricity (known as the breakdown voltage). In examples, the one or more centering gaskets 460 is a seal that retains the air, as an insulator, within the tunnel cavity 453 around the transmission core 420.

In examples, when air is enclosed in a confined space (e.g., between the one or more centering gaskets 460 around the transmission core 420), it reduces the ability of heat to be transferred by convection. For example, air traps heat, and reduces heat loss in cold environments and heat gain in warm environments. The air, as the insulator, is confined with the shell body 455 and reduces external applications of heat from transferring to the transmission core 420. The insulator 430, as air, reduces signal loss.

In some examples, signal loss increases the difficulty in phase matching of electrical systems. Phase matching in electrical systems such as coaxial cables, high-frequency signal applications such as telecommunications, radio frequency (RF) transmissions, and data communications refers to the process of ensuring that multiple signal paths or cables have the same electrical length, thereby causing the signals to arrive at their destination in phase with each other. Phase matching, for example, maintains a signal across the length of the electrical pathway and minimizes phase errors that lead to signal degradation. In examples, the insulator 430, as air, increases phase matching occurrences between associated electrical pathways, such as through the conduit body 150, as illustrated in FIG. 1.

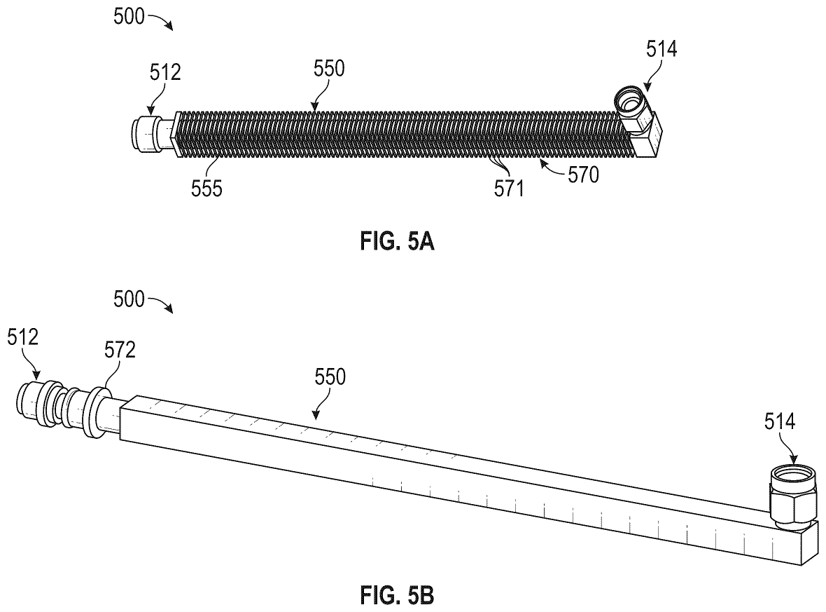

Illustrated in FIGS. 5A and 5B are examples of components associated with an electrical conduit 500 that dissipate heat from the electrical conduit 500. The electrical conduit 500 is, for example, similar to the electrical conduits illustrated in FIGS. 1-4 having components associated and discussed related to FIGS. 2, 3 and 4, such as a conduit body 550, a first electrical connector 512 and a second electrical connector 514. The electrical conduit 500 for example, transmits high frequency signals from the first electrical connector 512 to the second electrical connector 514. In examples, the first electrical connector 512 and the second electrical connector 514 are F-type connectors or N-type connectors, or other similar connectors suitable for receiving or transmitting high frequency signals.

To assist with dissipating heat from the electrical conduit 500, as illustrated in FIG. 5A, a heat sink 570 is formed on, joined with or extends from a shell body 555. For example, the heat sink 570 includes one or more fins 571 extending from the shell body 555. The one or more fins 571 assists in dissipating heat away from the shell body 555, such as the heat generated during the transmission of electrical signals from the first electrical connector 512 to the second electrical connector 514 and within the conduit body 550.

In other examples, as illustrated in FIG. 5B, a bulkhead 572 is coupled with one of the first electrical connector 512 or the second electrical connector 514 to dissipate heat away from the respective electrical connector. The bulkhead 572 is coupled with the first electrical connector 512 to, for example, reduce the temperature transmitted through a transmission core (e.g., transmission cores 120, 220, 320, 420) and the tunnel cavity (e.g., tunnel cavity 253, 353, 453). Reducing the temperature at or proximate to the first electrical connector 512 or reduces the weakening of an electrical signal transmitted through the electrical conduit 500.

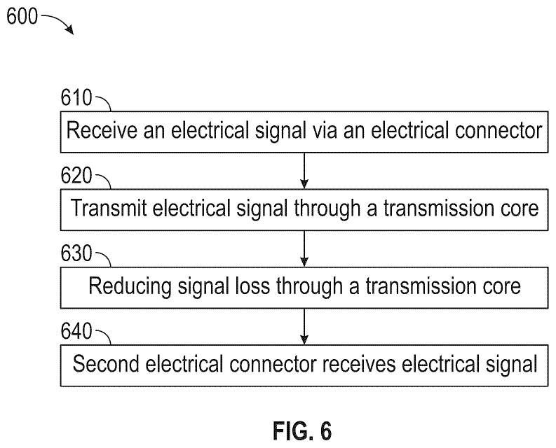

Illustrated in FIG. 6 is an example of a method for minimizing electrical signal loss through an electrical adapter, such as an electrical conduit as illustrated related to FIGS. 1-5A and 5B. In an example of the method an electrical signal is transmitted from an external source, such as a control system, computer, processor or the like and thereby received by a first electrical connector, as indicated in 610. The first electrical connector is positioned proximate to a first end portion of a conduit body, such as an end portion of the shell body.

The electrical signal is, for example, transmitted through a transmission core, as indicated in 620. The transmission core includes a first end segment and a second end segment. The first end segment is in communication with the first electrical connector and the second end segment is in communication with the second electrical connector. The transmission core is, for example, suspended within a tunnel cavity where the tunnel cavity extends within the shell body from the first end portion to the second end portion. For example, a gap is formed between the transmission core and an inner shell wall.

An air insulator, for example, extends around the transmission core, such as the gap. The air insulator, as discussed related to FIGS. 2 and 3, reduces signal loss during transmission of an electrical signal from the first electrical connector to the second electrical connector, as indicated in 630.

The electrical signal is received by the second electrical connector, as indicated in 640. The second electrical connector is in communication with a second end segment of the transmission core. The second electrical connector is, for example, positioned a second end portion of the shell body, such as at the second end portion of the electrical conduit. The second end electrical connector is, for example connected or in communication with a receiving control system.

In some examples, heat is removed from the electrical system with one or more heat sinks. For example, one or more heat sink fins are coupled with the shell body. The heat sink fins, for example assist in dispersing heat generated within the electrical conduit. In another example, a bulkhead is coupled with one or more of the first electrical connector or the second electrical connector. The bulkhead is formed to dissipate heat before the signal enters the electrical conduit and is transmitted through the transmission core. In another example, a bulkhead is coupled with the second electrical connector. The bulkhead coupled with the second electrical connector to dissipate heat generated during transmission of the signal through the transmission core.

In some examples, the shell body is formed from an unpliant material. In examples, an unpliant material assists in maintaining the position of the transmission core within the tunnel cavity. Maintaining the position of the transmission core in turn maintains the position of the air insulator surrounding the transmission core. For example, transmission core has substantially consistent air insulation surrounding transmission core.

### Aspects

Aspect 1 can include subject matter such as n electrical conduit, comprising: a shell body spanning between a first end portion and a second end portion; a first electrical connector positioned at the first end portion; a second electrical connector positioned at the second end portion; a transmission core positioned between the first end portion and the second end portion within the shell body; and a tunnel cavity extending through the shell body; wherein the transmission core is suspended within the tunnel cavity and spaced from the shell body; wherein the first electrical connector and the second electrical connector are in communication with the transmission core.

Aspect 2 can include, or can optionally be combined with the subject matter of Aspect 1, to optionally include the shell body includes an unpliant material.

Aspect 3 can include, or can optionally be combined with the subject matter of one or any combination of Aspects 1 or 2 to optionally include one or more centering gaskets positioned within the tunnel cavity; wherein the one or more centering gaskets are configured to maintain the position of the transmission core within the tunnel cavity.

Aspect 4 can include, or can optionally be combined with the subject matter of one or any combination of Aspects 1 to 3 to optionally include the tunnel cavity includes an air insulator.

Aspect 5 can include, or can optionally be combined with the subject matter of one or any combination of Aspects 1 to 4 to optionally include one or more bulkheads positioned proximate to at least one of the first end portion or the second end portion; wherein the shell body includes an unpliant material configured to withstand temperatures greater than 600 degrees Celsius.

Aspect 6 can include, or can optionally be combined with the subject matter of one or any combination of Aspects 1 to 5 to optionally include a plurality of heat distribution fins positioned on an outer surface of the shell body.

Aspect 7 can include, or can optionally be combined with the subject matter of one or any combination of Aspects 1 to 6 to optionally include the shell body is at least 5 inches (12.7 centimeters) long.

Aspect 8 can include, or can optionally be combined with the subject matter of one or any combination of Aspects 1-7 to optionally include the length of the shell body is based on the width of the tunnel cavity.

Aspect 9 can include subject matter such as an electrical adapter comprising: an elongate shell body including: a first end portion; a second end portion; an outer shell wall; an inner shell wall, defining a tunnel cavity, the inner shell wall and the tunnel cavity extending between the first end portion and the second end portion; a transmission core bridging the elongate shell body within the tunnel cavity; wherein the transmission core is positioned away from the inner shell wall; wherein the tunnel cavity extending around the transmission core includes an air insulator; a first connector in communication with a first end segment of the transmission core; and a second connector in communication with a second end segment of the transmission core.

Aspect 10 can include, or can optionally be combined with the subject matter of one or any combination of Aspect 9 to optionally include wherein the elongate shell body is formed from an unpliant material including at least one or more of titanium, stainless steel alloys, molybdenum and nickel.

Aspect 11 can include, or can optionally be combined with the subject matter of one or any combination of Aspect 9 or 10 to optionally include one or more heat exchangers.

Aspect 12 can include, or can optionally be combined with the subject matter of one or any combination of Aspects 9-10 to optionally include the elongate shell body is configured to withstand temperatures exceeding at least 600 degrees Celsius.

Aspect 13 can include, or can optionally be combined with the subject matter of one or any combination of Aspects 9-12 to optionally include the length of the elongate shell body is based on the width of the tunnel cavity.

Aspect 14 can include, or can optionally be combined with the subject matter of one or any combination of Aspects 9-13 to optionally include the length of the elongate shell body is at least 5 inches (12.7 centimeters).

Aspect 15 can include, or can optionally be combined with the subject matter of one or any combination of Aspects 8-14 to optionally include the first connector and the second connector include coaxial connections.

Aspect 16 can include, or can optionally be combined with the subject matter of one or any combination of Aspects 8-15 to optionally include one or more centering gaskets positioned within the tunnel cavity; wherein the one or more centering gaskets are configured to retain the transmission core within the tunnel cavity substantially equidistant from the inner wall.

Aspect 17 can include subject matter such as a method of minimizing an electrical signal loss through an electrical adapter comprising: receiving an electrical signal with a first electrical connector, the first electrical connector positioned at a first end portion of a shell body; transmitting the electrical signal through a transmission core; wherein a first end segment of the transmission core is in communication with the first electrical connector, the transmission core suspended within a tunnel cavity and the tunnel cavity extending through the shell body; receiving the transmitted electrical signal with a second electrical connector in communication with a second end segment of the transmission core, the second electrical connector positioned at a second end portion of the shell body; and insulating the transmission core with an air insulation; wherein the air insulation surrounds the transmission core.

Aspect 18 can include, or can optionally be combined with the subject matter of one or any combination of Aspect 17 to optionally include distributing heat generated by the transmitting of the electrical signal with one or more heat exchangers coupled with the shell body.

Aspect 19 can include, or can optionally be combined with the subject matter of one or any combination of Aspect 17 or 18 to optionally include the shell body is formed from an unpliant material.

Aspect 20 can include, or can optionally be combined with the subject matter of one or any combination of Aspects 8-15 to optionally include the length of the shell body is dependent on the width of the tunnel cavity.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electrical conduit, comprising:
a shell body spanning between a first end portion and a second end portion;
a first electrical connector positioned at the first end portion;
a second electrical connector positioned at the second end portion;
a transmission core positioned between the first end portion and the second end portion within the shell body; and
a tunnel cavity extending through the shell body;
wherein the transmission core is suspended within the tunnel cavity and spaced from the shell body;
wherein the first electrical connector and the second electrical connector are in communication with the transmission core.

2. The electrical conduit of claim 1, wherein the shell body includes an unpliant material.

3. The electrical conduit of claim 1, including:
one or more centering gaskets positioned within the tunnel cavity;
wherein the one or more centering gaskets are configured to maintain the position of the transmission core within the tunnel cavity.

4. The electrical conduit of claim 1, wherein the tunnel cavity includes an air insulator.

5. The electrical conduit of claim 1, including one or more bulkheads positioned proximate to at least one of the first end portion or the second end portion;
wherein the shell body includes an unpliant material configured to withstand temperatures greater than 600 degrees Celsius.

6. The electrical conduit of claim 1, including a plurality of heat distribution fins positioned on an outer surface of the shell body.

7. The electrical conduit of claim 1, wherein the shell body is at least 5 inches (12.7 centimeters) long.

8. The electrical conduit of claim 1, wherein a length of the shell body is based on a width of the tunnel cavity.

9. An electrical adapter comprising:
an elongate shell body including:
a first end portion;
a second end portion;
an outer shell wall;
an inner shell wall, defining a tunnel cavity, the inner shell wall and the tunnel cavity extending between the first end portion and the second end portion;
a transmission core bridging the elongate shell body within the tunnel cavity;
wherein the transmission core is positioned away from the inner shell wall;
wherein the tunnel cavity extending around the transmission core includes an air insulator;
a first connector in communication with a first end segment of the transmission core; and
a second connector in communication with a second end segment of the transmission core.

10. The electrical adapter of claim 9, wherein the elongate shell body is formed from an unpliant material including at least one or more of titanium, stainless steel alloys, molybdenum and nickel.

11. The electrical adapter of claim 9, including one or more heat exchangers.

12. The electrical adapter of claim 9, wherein the elongate shell body is configured to withstand temperatures exceeding at least 600 degrees Celsius.

13. The electrical adapter of claim 9, wherein a length of the elongate shell body is based on a width of the tunnel cavity.

14. The electrical adapter of claim 9, wherein a length of the elongate shell body is at least 5 inches (12.7 centimeters).

15. The electrical adapter of claim 9, wherein the first connector and the second connector include coaxial connections.

16. The electrical adapter of claim 9, including one or more centering gaskets positioned within the tunnel cavity;
wherein the one or more centering gaskets are configured to retain the transmission core within the tunnel cavity substantially equidistant from the inner wall.

17. A method of minimizing an electrical signal loss through an electrical adapter comprising:
receiving an electrical signal with a first electrical connector, the first electrical connector positioned at a first end portion of a shell body;
transmitting the electrical signal through a transmission core;
wherein a first end segment of the transmission core is in communication with the first electrical connector, the transmission core suspended within a tunnel cavity and the tunnel cavity extending through the shell body;
receiving the transmitted electrical signal with a second electrical connector in communication with a second end segment of the transmission core, the second electrical connector positioned at a second end portion of the shell body; and
insulating the transmission core with an air insulation;
wherein the air insulation surrounds the transmission core.

18. The method of minimizing the electrical signal loss of claim 17, including:
distributing heat generated by the transmitting of the electrical signal with one or more heat exchangers coupled with the shell body.

19. The method of minimizing the electrical signal loss of claim 17, wherein the shell body is formed from an unpliant material.

20. The method of minimizing the electrical signal loss of claim 17, wherein a length of the shell body is dependent on a width of the tunnel cavity.
